(19) United States
(12) Patent Application Publication
(10) Pub. No.: US 2022/0362893 A1
(43) Pub. Date: Nov. 17, 2022

(54) TRANSPORT UNIT FOR TRANSPORTING PRINTED CIRCUIT BOARDS, AND SOLDERING SYSTEM

(71) Applicant: ERSA GmbH, Wertheim (DE)

(72) Inventors: Ruppert Elmar, Mespelbrunn (DE); Thomas Huhler, Neubrunn (DE); Benedict Fleischmann, Neubrunn (DE); Simon Hame, Kreuzwertheim (DE)

(73) Assignee: ERSA GmbH, Wertheim (DE)

(21) Appl. No.: 17/771,085

(22) PCT Filed: Oct. 14, 2020
(86) PCT No.: PCT/EP2020/078922

§ 371 Date: Apr. 22, 2022

(30) Foreign Application Priority Data
Oct. 24, 2019 (DE) 10 2019 128 780.4

(51) Int. Cl. B23K 37/04; B23K 1/00; B23K 3/08; H05K 13/00

(52) U.S. Cl. CPC B23K 37/0408; B23K 1/0016; B23K 3/085; H05K 13/0061; B23K 2101/42

(57) ABSTRACT

A transport unit for transporting printed circuit boards along a direction of transport within at least one zone of a soldering system, in particular a reflow soldering system, characterized in that a base part is provided with an output shaft that can be driven, and with at least two output wheels which are rotatably coupled to the output shaft, in that at least two drive parts which can be releasably fastened on and removed from the base part are each provided with a drive wheel in such a manner that the drive parts have drive rollers which are rotatably coupled to the drive wheel, and which act on the printed circuit board to transport the printed circuit board through the zone, and in that, when the drive parts are fastened to the base part, each of the output wheels is in engagement with the associated drive wheel.

### BACKGROUND

The invention relates to a transport unit for transporting printed circuit boards along a direction of transport within at least one zone of a soldering system, such as a reflow soldering system, for example. The invention also relates to soldering systems, in particular reflow soldering systems, for continuous soldering of printed circuit boards in a process channel along a direction of transport, wherein at least one preheating zone, at least one soldering zone, and at least one cooling zone are provided in the process channel, wherein a pressure chamber is provided in the soldering zone, which has a base part and has a cover part that can be raised relative to the base part during operation of the reflow soldering system. The pressure chamber is in particular a vacuum chamber; however, it is also conceivable that the pressure chamber is designed as an overpressure chamber.

Such reflow soldering systems are used in particular to solder so-called SMD components (surface mounted devices) onto the surface of printed circuit boards using solder paste. The solder paste, which is in particular a mixture of solder metal granules, flux, and pasty components, is applied or printed onto the surface of the printed circuit boards for the reflow soldering. The components to be soldered are then placed in the solder paste. In the reflow soldering process, the item to be soldered—that is, the assembly consisting of the printed circuit board, solder paste, and components to be soldered—is preheated along the process channel in the preheating zone, and is heated in the soldering zone to a temperature that is above the melting point of the solder paste. The solder paste melts as a result, and the solder points are formed. The item to be soldered is cooled in the cooling zone until the melted solder solidifies before it is removed from the reflow soldering system.

In reflow soldering systems, the process channel is covered by a covering hood in order to be able to provide the desired temperature profile and a defined atmosphere in the process channel. Furthermore, process gases form in the process channel, which can be discharged from the process channel and purified.

In order to achieve a better process outcome, it is known to provide a negative pressure chamber or a vacuum chamber in the soldering zone, and to set it up in such a manner that the soldering process takes place in the vacuum chamber with a negative pressure that is significantly below atmospheric pressure. This ensures that gas and air bubbles, flux residues, and other contaminants are drawn off by the vacuum during the soldering process, which increases the quality of the soldered connections. Accordingly, the quality of the soldered connection can be improved by using an overpressure chamber within which the soldering process takes place.

Reflow soldering systems with vacuum chambers are known from DE 10 2009 028 865 B4 and from US 2009 0014503 A1. DE 201 02 064 U1 and DE 199 11 887 C1 also disclose reflow soldering systems which provide a vacuum chamber which has a base part and a cover part in the form of a vacuum bell which can be raised relative to the base part. The cover part can be raised off of the base part for the process of moving the item to be soldered into and out of the vacuum chamber.

In addition, a two-part conveyor system is known from U.S. Pat. No. 4,844,231 A, wherein a drive device is connected to conveyor rollers via belts for the purpose of driving production parts. A transport device for transport containers is disclosed in DE 199 00 461 A1, wherein the force can be transmitted by gears.

### SUMMARY

The invention is based on the object of specifying an at the outset transport unit which can be used in particular in a pressure chamber of the soldering system, and which has advantageous properties.

This problem is solved by a transport unit having the features of claim 1. It is consequently provided in particular that a base part is provided with an output shaft that can be driven in particular by a rotary drive, and with at least two output wheels rotatably coupled to the output shaft, in that at least two drive parts that can be releasably fastened to and removed from the base part are each provided with a drive wheel in such a manner that the drive parts have drive rollers which are rotatably coupled to the respective drive wheels, and which act on the printed circuit board to transport the printed circuit board through the zone, and in that, when the drive part is fastened to the base part, each output wheel is in engagement with the associated drive wheel. Consequently, when the drive part is removed from the base part, the drive wheel is no longer in engagement with the output wheel. The drive wheel and the output wheel in this case are designed as gears.

In addition, receiving parts which extend in the direction of transport are provided for receiving and for releasably fastening the drive parts, wherein the receiving parts each have an output wheel which can be brought into engagement with the drive wheel and can be driven by the output shaft. Each of the drive parts can consequently be fastened to an associated receiving part and/or removed from the associated receiving part. A fastening device, by means of which each of the drive parts can be fastened to the respective receiving parts, is preferably provided. It can be contemplated that a screw connection, which in particular is manually operable, is provided.

Such a transport unit has the advantage that the drive parts can be exchanged in a simple manner. To release the rotary coupling between the output wheel and the drive wheel, it is only necessary to remove the drive part from the base part, as a result of which the drive wheel is lifted off the output wheel. When the drive part is placed on the base part, the drive wheel is in direct engagement with the output wheel. The reason it is necessary to remove the drive parts is that they have to be regularly checked, cleaned, serviced and, if necessary, repaired. In particular, if the transport unit is used in a pressure chamber of the reflow soldering system, it is exposed to high temperatures and high mechanical loads. The fact that the drive parts can be easily removed and replaced reduces the downtime of the reflow soldering system, and thus increases its productivity.

Advantageously, the drive parts provide a plurality of drive rollers arranged one behind the other in the direction of transport, with adjacent drive rollers being rotatably coupled to one another via gears, and with at least one of the gears being rotatably coupled to the drive wheel. By providing a plurality of drive rollers arranged one behind the other, a reliable transport of the printed circuit boards through each of the zones can be ensured. Due to the fact that the individual drive rollers are rotatably coupled to each other via gears, there is no sliding movement between the components, which means that the transport unit requires comparatively little maintenance, and comparatively small amounts of lubricants are needed. In addition, the drive parts have a high level of robustness; in particular, they can be easily removed, replaced, and/or cleaned as such.

The base part is advantageously designed in the manner of a frame, with two side parts extending in the direction of transport, and with two struts extending in the transverse direction, running transverse to the direction of transport. Such a base part can preferably be removed in a simple manner from the given zone of the soldering system in order to replace, clean, or service the entire transport unit when necessary. This has proven particularly useful if the transport unit is used inside a pressure chamber of the soldering system.

The drive shaft preferably extends in the transverse direction, and is arranged in a rotatably mounted manner on the two side parts. This makes it possible for the drive shaft to drive a plurality of drive parts and/or their drive wheels and drive rollers provided between the side parts.

In addition, it is advantageous if at least one receiving part, and preferably a plurality of receiving parts, are arranged in a manner allowing adjustment in the transverse direction on the struts. Such an adjustment in the transverse direction can be used for adapting to the width of the printed circuit boards in the transverse direction. The receiving parts, and thus also the drive parts, can be adjusted according to the width of the circuit board to be soldered. For this purpose, a suitable bearing can be provided between the receiving parts and the struts, for example a plain bearing or a bearing by means of roller bearings.

Furthermore, it is advantageous if the receiving parts each provide a coupling wheel which is rotatably coupled to the drive wheel on the one hand and to the output shaft on the other hand. The coupling wheel is preferably arranged in an axially displaceable manner on the output shaft, such that the receiving part can slide and be adjusted in the transverse direction, while at the same time, a rotary coupling between the output shaft and the coupling wheel is ensured. It can be contemplated that the output shaft has a non-circular cross section, and is designed, for example, as a square shaft, and in particular as a square or hexagonal shaft. The coupling wheel then has a receiving contour that is complementary to the outer contour of the drive shaft, such that the coupling wheel is arranged to be displaceable on the output shaft, but is nevertheless rotatably coupled to it.

It has also proven to be advantageous if at least one adjusting shaft is provided, which extends in the transverse direction and is coupled to at least one receiving part in such a manner that the receiving part can be displaced in the transverse direction by the rotation of the adjusting shaft. The adjusting shaft can in particular be designed as a spindle shaft, in which case the given receiving part then has a spindle nut that works together with the spindle shaft. By rotating the spindle shaft, the given receiving part can be adjusted in the transverse direction. Advantageously, the adjusting shaft, corresponding to the output shaft, is rotatably mounted on the side parts of the base part. Furthermore, the spindle nut can itself be rotated; this allows adjusting the bearing play between the width adjusting shaft and the spindle nut, and/or allows compensating at a later time for play caused by wear during operation.

A preferred embodiment provides two edge receiving parts, each for receiving one edge drive part, wherein the drive rollers of one edge drive part face the drive rollers of the other edge drive part, and are arranged in such a manner that, when the transport unit is in operation, the printed circuit board rests, in the region of its free longitudinal edges, on the drive rollers. In the region of the free longitudinal edges, there are generally no electronic components on the printed circuit boards, such that the drive rollers can advantageously engage with the printed circuit board to transport it.

It is also advantageous if the edge drive parts provide longitudinal guides for guiding the printed circuit boards in the direction of transport. During operation, the longitudinal guides then act on the free edges of the printed circuit boards, such that they can be guided securely through the soldering system in the direction of transport.

Furthermore, it is advantageous if at least one center receiving part is provided between the two edge receiving parts, for the purpose of receiving a center drive part. Such a center drive part then forms a center support, which is necessary in particular when comparatively large printed circuit boards will be soldered. The center drive part prevents the circuit board from bending or sagging in its center region, and also ensures functionally secure transport.

In addition, it is advantageous if the transport unit has two transport tracks running in the direction of transport, with two edge receiving parts being provided for each transport track and, optionally, a center receiving part also being provided between the respective edge receiving parts. As a result, the capacity of the transport unit, and thus also of the entire soldering system, can be increased overall.

It is advantageous if a plurality of adjusting shafts is provided—on the one hand, an adjusting shaft for adjusting the edge receiving parts, and a further adjusting shaft for adjusting the center receiving parts. As a result, the overall width of each of the transport tracks can be adjusted in a simple manner.

The stated object is also achieved by a soldering system as mentioned at the outset, in particular a reflow soldering system, which is characterized in that a transport unit according to the invention is provided at least in one of the zones and/or in the pressure chamber. As already mentioned, it is preferred to provide such a transport unit in the pressure chamber, since on the one hand the drive parts of the transport unit are easily exchangeable, and on the other hand the transport unit itself is also easily exchangeable.

Further details and advantageous embodiments of the invention can be found in the following description, on the basis of which one embodiment of the invention will be described and explained in more detail.

### BRIEF DESCRIPTION OF THE DRAWINGS

In the drawings:

FIG. 1 is a reflow soldering system in side view;

FIG. 2 is the reflow soldering system according to FIG. 1 in a front view;

FIG. 3 is the top view of the soldering zone of the reflow soldering system, without the cover;

FIG. 4 is a perspective view of a two-track transport unit;

FIG. 5 is the transport unit according to FIG. 4, without a side cover and without a side part;

FIG. 6 shows individual parts of the transport unit according to FIG. 4, with the drive part removed;

FIG. 7 is a view of a drive part attached to a receiving part.

### DETAILED DESCRIPTION

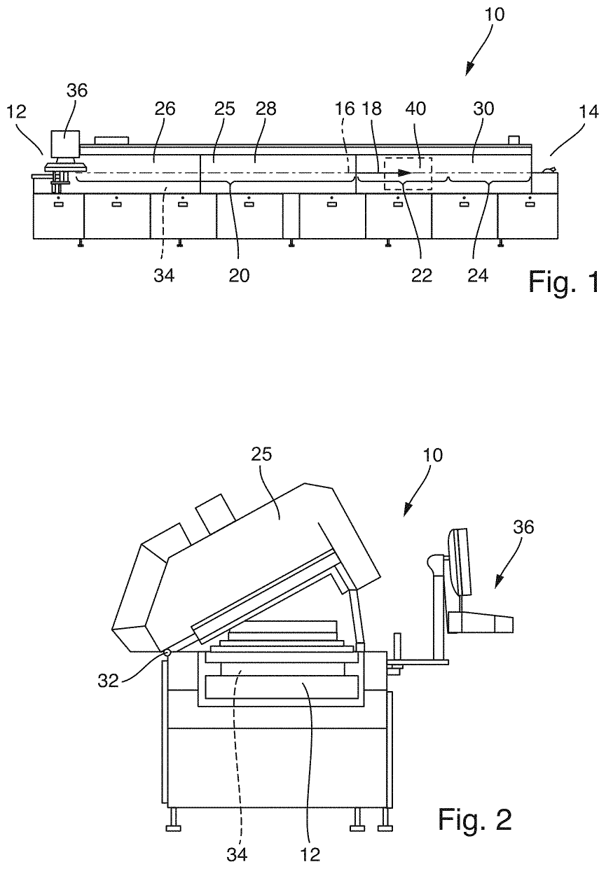

FIG. 1 shows a reflow soldering system 10 for continuous soldering of items to be soldered. The reflow soldering system 10 has an entrance 12 and an exit 14, wherein the items to be soldered enter the reflow soldering system 10 via the entrance 12, and are removed from the reflow soldering system 10 via the exit 14. The item to be soldered is transported through the reflow soldering system 10 along a direction of transport 18 of a process channel 16 indicated in FIG. 1.

A preheating zone 20, a soldering zone 22, and a cooling zone 24 are provided in the process channel 16. In the case of the reflow soldering system 10 shown in FIG. 1, a machine casing 25 with three sections 26, 28 and 30 is provided for covering the process channel 16.

As is clear from FIGS. 1 and 2, a communication unit 36 with a display screen and an input device is provided, by means of which communication can take place with a machine controller of the reflow soldering system 10.

The item to be soldered, that is, the printed circuit board configured with solder paste and fitted with electronic components, is first heated in the preheating zone 20 to a temperature which is below the melting temperature of the solder paste. In the soldering zone 22, the printed circuit board is heated for a specific period to a process temperature which is above the melting point of the solder paste, such that it melts in the soldering zone to solder the electronic components to the printed circuit board. The item being soldered is cooled in the cooling zone 24, such that the liquid solder solidifies before the item being soldered is removed at the exit 14 of the reflow soldering system 10.

A transport system 34 is provided within the reflow soldering system 10 for transporting the printed circuit boards along the direction of transport 18.

As is clear from the front view of FIG. 2, the covering hood 25 can be pivoted open about a pivot axis 32 extending parallel to the direction of transport 18. The transport system 34 is accessible by pivoting the covering hood 25—to allow visual inspection, maintenance, cleaning, setup, replacement, and, optionally, repair.

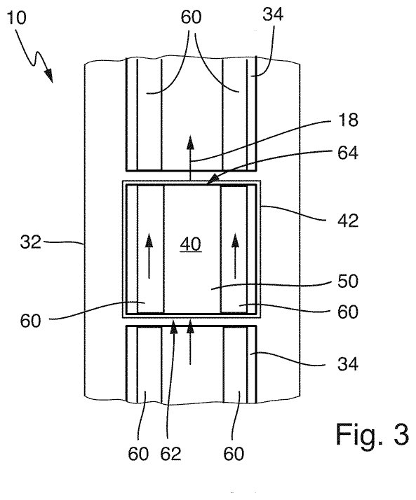

In the soldering zone 22, there is a pressure chamber in the form of a vacuum chamber 40, which is formed by a base part 42—shown in the top view according to FIG. 3—and by a cover part, which is not shown in the figures, with which the base part 42 can be closed off.

During operation of the reflow soldering system 10, the cover part can be lifted off the base part 42 by means of a lifting mechanism. It is necessary to lift the cover part in order to be able to move the printed circuit boards into the vacuum chamber 40. As soon as the printed circuit boards are situated in the vacuum chamber 40, the cover part is lowered so that it comes to rest on the base part 42. In a next step, the vacuum chamber 40 is evacuated with a vacuum pump (not shown), such that a suitable negative pressure is created in the vacuum chamber 40. Due to the negative pressure, air which is contained in the liquid solder, in particular, is expelled. After a brief application of negative pressure to the vacuum chamber 40, the cover part is raised via a corresponding activation of the lifting mechanism, such that the printed circuit boards can move out of the vacuum chamber 40. Advantageously, the printed circuit boards move through the vacuum chamber 40 within the described process at a constant speed or at a variable speed.

In the top view according to FIG. 3, the base part 42 of the pressure chamber 40, and the transport unit 50 provided in the base part 42, are shown schematically. A total of two transport tracks 60 running parallel to one another is provided, along which printed circuit boards can be transported next to one another along the direction of transport 18 through the process chamber 16 and the vacuum chamber 40. The vacuum chamber 40 provides a chamber entrance 62 in which circuit boards coming from the transport system 34 are transferred to the transport unit 50, and a chamber exit 64 in which the circuit boards are transferred back to the transport system 34.

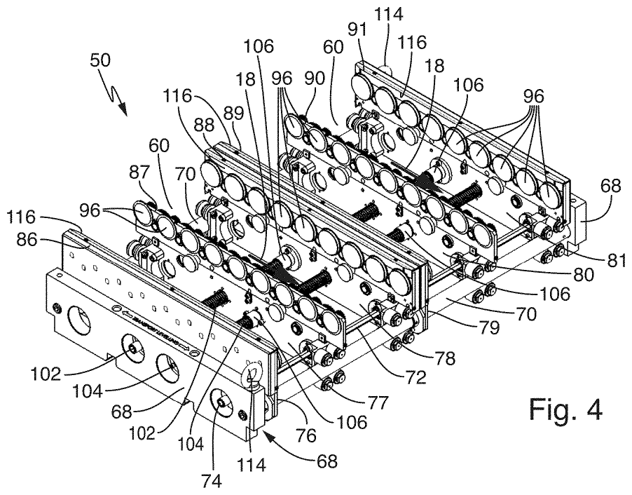

The transport unit 50, which can be inserted into the pressure chamber 40 and/or into the base part 42 of the pressure chamber 40, is shown in FIG. 4. The transport systems 34 indicated in FIG. 3 can be transport systems which correspond to the transport unit 50. However, it is also conceivable that differently designed transport systems are used there, since these transport systems 34 are subject to less stress than the transport unit 50 which is used inside the pressure chamber 40.

The transport unit 50 comprises a base part 66, which is designed like a frame and has two side parts 68 extending in the direction of transport 18, and two struts 70 running in the transverse direction. Also provided on the base part 66 is an output shaft 72 which is rotatably mounted on the side parts 68 and which can be driven at its free end 74 via a rotary drive, which is not shown in detail.

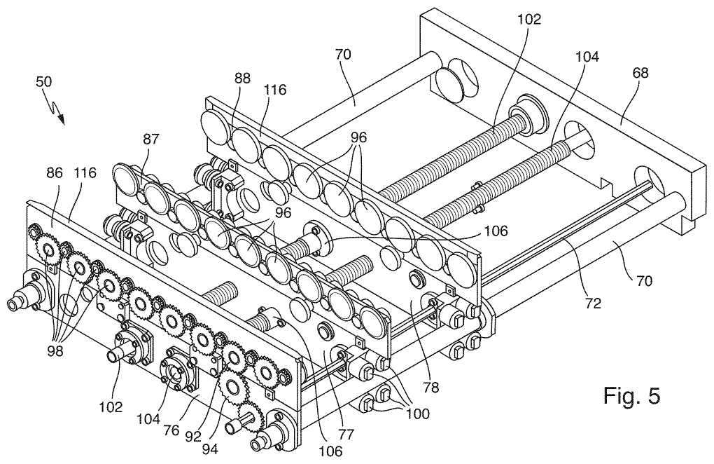

On the base part 66 between the side parts 68, there is a total of six receiving parts 76 to 81, on which drive parts 86 to 91 are provided which can be releasably fastened and removed. FIG. 5 shows the transport system 50 with only one side part 68, and with only the three receiving parts 76 to 78 and the three drive parts 86 to 88.

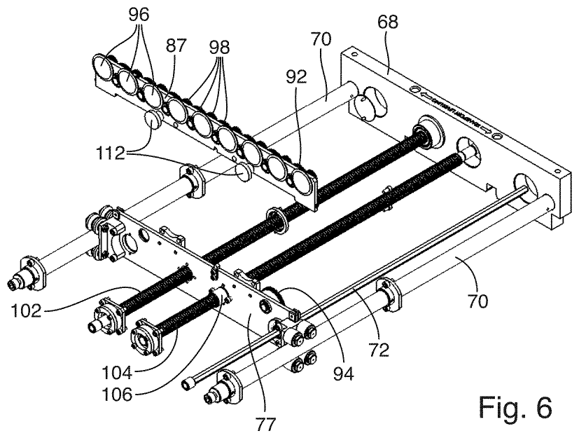

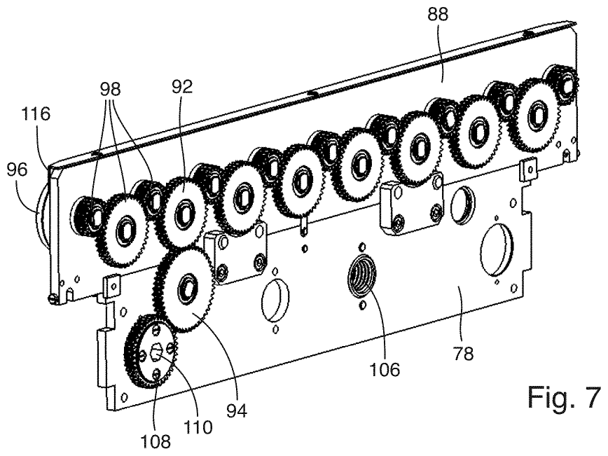

Each of the drive parts 86 to 91 has a drive wheel 92, and each of these is in engagement with, in the assembled state, as can be seen in particular from FIG. 5 and FIG. 7, an output wheel 94, which is provided on the base part 68 and/or on the given receiving part 76 to 81. The drive wheels 92 and the output wheels 94 are arranged coaxially with one another, and also coaxially with the output shaft 72 and with the struts 70. The arrangement is such that, when the drive parts 86 to 91 are removed, as shown in FIG. 6, each of the drive wheels 92 is lifted off the given output wheel 94, and accordingly is no longer in engagement with the given output wheel 94.

Each of the drive parts 86 to 91 also has drive rollers 96 rotatably coupled to the respective associated drive wheels 92, on which drive rollers the printed circuit boards come to rest during operation, and which transport the printed circuit boards through the given zone 18, 20, 22 and/or through the pressure chamber 40. As is also clear from FIGS. 4, 5 and 6, a plurality of drive rollers 96 arranged one behind the other in the direction of transport 18 is provided on the drive parts 86 to 91, wherein adjacent drive rollers 96 are rotatably coupled to one another via gears 98. One of these gears forms the drive wheel 92 which, as is clear from FIG. 7, is in engagement with the output wheel 94 in the assembled state.

As explained in relation to FIG. 3, the transport unit 50 can be used to transport printed circuit boards along the two transport tracks 60. The receiving parts 76, 77 and 78 with the drive parts 86, 87 and 88 are assigned to one of the transport tracks 60 in this case. The receiving parts 79, 80, 81 with the drive parts 89, 90, 91 are assigned to the second transport track 60.

The receiving parts 76, 77, 78 and the drive parts 86, 87, 88 of only one transport track 60 are shown in FIG. 5. The receiving parts 76, 78 are designed as edge receiving parts, and the central receiving part 77 is designed as a center receiving part. The drive parts 86, 88 are designed as edge drive parts, and the central drive part 87 is designed as a center drive part. The edge receiving parts 76, 78 serve the purpose of receiving edge drive parts 86, 88, and the central receiving part 77 serves the purpose of receiving the center drive part 87. The arrangement is such that the drive rollers 96 of the edge drive parts 86, 88 are arranged facing one another, such that during operation of the transport unit 50, each printed circuit board comes to rest on the respective drive rollers 96 in the region of its free longitudinal edges. The edge drive parts 86, 88 and 89, 91 have longitudinal guides 116 which serve to guide the circuit boards in the direction of transport 18 during operation of the system. The center drive part 87 is provided to support the printed circuit boards in the central region, and additionally drives the central regions of the printed circuit board.

The receiving parts 79, 80 and 81 and the associated drive parts 89, 90 and 91, which form the second transport track 60, correspond in structure to the receiving parts 76, 77, 78 and drive parts 86, 87, 88 of the first transport track 60.

In order to be able to adjust the width of each of the transport tracks 60 and/or the position of the drive parts 86 to 91 in the transverse direction, the receiving parts 78 to 81 are arranged in a manner allowing movement on the struts 70 by means of guide rollers 100. To adjust the receiving parts 76 to 81, two spindle shafts 102 and 104 are provided which are rotatably mounted on the side parts 68 and which can be driven via rotary drives which are not shown in the figures. The spindle shaft 102 is coupled to the edge receiving parts 78 and 81 via spindle nuts 106 to allow movement, such that when the spindle shaft 102 rotates, the two receiving parts 78 and 81, and thus the drive parts 88 and 91, can be adjusted. The spindle shaft 104 is coupled to the center receiving parts 77 and 80 via spindle nuts to allow movement, such that when the spindle shaft 104 is rotated, the receiving parts 77 and 80 and thus the drive parts 87 and 90 can be adjusted in the transverse direction.

In order to enable the output wheels 94 to be rotatably coupled to the output shaft 72 even when the receiving parts 76 to 81 are being adjusted in the transverse direction, the receiving parts 76 to 81 have coupling wheels 108 rotatably coupled to the output wheels 94, which is particularly clear from FIG. 7. The coupling gears 108 each have a receiving contour 110 that is complementary to the cross section of the output shaft 72, such that the coupling gears 108 and thus the associated receiving parts 76 to 81 can be displaced with the drive parts 89 to 91 on the output shaft 72 in the transverse direction, and nevertheless are still rotatably coupled to the output shaft 72. In the embodiment shown in the figures, the output shaft 72 has a hexagonal cross section, and the receiving contour 110 provided on each of the coupling wheels 108 is designed as a hexagonal recess.

As is clear from FIG. 6, the drive parts 86 to 91 can be removed vertically from the associated receiving parts 76 to 81 in a simple manner. All that is required for this purpose is fastening means, which are designed as hand-operated fastening screws 112 in FIG. 6. After the fastening screws 112 have been unscrewed, and each of the drive parts 86 to 91 has been removed, each of the drive wheels 92 also lifts off from the associated output wheel 94. When each of the drive parts 86 to 91 is placed back onto the respective receiving parts 76 to 81, each of the drive wheels 92 comes back into engagement with the associated output wheel 94.

As is clear from FIG. 4, retaining lugs 114 are provided on the frame, via which the entire transport unit 50 can be removed from the soldering system 10 or from the corresponding zone 20, 22, 24 or the pressure chamber 40 in a simple manner.

The reflow soldering system 10 described or the drive unit 50 described has the advantage that the individual drive parts 86 to 91 can be exchanged, inspected, serviced and cleaned in a simple manner. Furthermore, the entire transport unit 50 can also be exchanged. The drive parts 86 to 91 described are comparatively robust, since only gears, and no chains or belts, are used. Furthermore, intensive and/or automatic lubrication can also be dispensed with. The embodiment with gears is also significantly less sensitive to contamination in the form of condensate or solder residue. Furthermore, in comparison to conventional chain drives, no chain tensioning device is required.

1. A transport unit for transporting printed circuit boards along a direction of transport within at least one zone of a soldering system, wherein a base part is provided with an output shaft that can be driven, characterized in that at least two output gears which are rotatably coupled to the output shaft are provided, in that at least two drive parts which can be releasably fastened on and removed from the base part are each provided with a drive gear in such a manner that the drive parts have drive rollers which are rotatably coupled to the drive gear, and which act on the printed circuit board to transport the printed circuit board through the zone, in that, when the drive parts are fastened to the base part, each of the output gears is in engagement with the associated drive gear, and in that receiving parts which extend in the direction of transport are provided on the base part for receiving and for releasably fastening the drive parts, wherein the receiving parts each have the output gear which can be brought into engagement with the drive gear and which can be driven by the output shaft.

2. The transport unit according to claim 1, characterized in that the drive parts have a plurality of drive rollers arranged one behind the other in the direction of transport, wherein adjacent drive rollers are rotatably coupled to one another via gears, and wherein at least one gear is rotatably coupled to the drive gear.

3. The transport unit according to claim 1, characterized in that the base part is designed in the manner of a frame, with two side parts extending in the direction of transport, and with two struts extending in the transverse direction, running transverse to the direction of transport.

4. The transport unit according to claim 3, characterized in that the arrangement is such that the frame can be releasably and removably arranged in the soldering system.

5. The transport unit according to claim 3, characterized in that the output shaft extends in the transverse direction and is arranged in a rotatably mounted manner on the two side parts.

6. The transport unit according to claim 3, characterized in that at least one receiving part is arranged in a manner allowing movement and adjustment on the struts in the transverse direction.

7. The transport unit according to claim 6, characterized in that the receiving parts each provide a coupling gear which is rotatably coupled to the output gear and to the output shaft, and which is arranged on the output shaft in a manner allowing axial displacement.

8. The transport unit according to claim 6, characterized in that at least one adjusting shaft is provided, which extends in the transverse direction and which is coupled to at least one receiving part in such a manner that the receiving part can be displaced in the transverse direction by the rotation of the adjusting shaft.

9. The transport unit according to claim 1, characterized in that two edge receiving parts are provided, each for receiving one edge drive part, wherein the drive rollers of one edge drive part face the drive rollers of the other edge drive part, and are arranged in such a manner that, when the transport unit is in operation, the printed circuit board rests, in the region of its free longitudinal edges, on the drive rollers.

10. The transport unit according to claim 9, characterized in that longitudinal guides for guiding the printed circuit boards in the direction of transport are provided on the edge drive parts.

11. The transport unit according to claim 9, characterized in that at least one center receiving part for the purpose of receiving a center drive part is provided between the edge receiving parts.

12. The transport unit according to claim 11, characterized in that the transport unit has two transport tracks running in the direction of transport, wherein at least one of two edge receiving parts and one center receiving part is provided for each transport track.

13. A soldering system for continuous soldering of printed circuit boards in a process channel along a direction of transport, wherein at least one preheating zone at least one soldering zone, and at least one cooling zone are provided in the process channel, wherein a pressure chamber is provided in the soldering zone, which has a base part and has a cover part which can be lifted relative to the base part during operation of the reflow soldering system, characterized in that a transport unit for transporting the printed circuit boards along the direction of transport within the at least one zone of a soldering system is provided at least in one of the zones and/or in the pressure chamber, wherein the base part is provided with an output shaft that can be driven, characterized in that at least two output gears which are rotatably coupled to the output shaft are provided, in that at least two drive parts which can be releasably fastened on and removed from the base part are each provided with a drive gear in such a manner that the drive parts have drive rollers which are rotatably coupled to the drive gear, and which act on the printed circuit board to transport the printed circuit board through the zone, in that, when the drive parts are fastened to the base part, each of the output gears is in engagement with the associated drive gear, and in that receiving parts which extend in the direction of transport are provided on the base part for receiving and for releasably fastening the drive parts, wherein the receiving parts each have the output gear which can be brought into engagement with the drive gear and which can be driven by the output shaft.
